(19) United States
(12) Patent Application Publication
(10) Pub. No.: US 2026/0068578 A1
(43) Pub. Date: Mar. 5, 2026

(54) SPATIAL GAS INJECTION FOR GAS DEPLETION AND GAS CONCENTRATION ADJUSTABILITY, AND RELATED PROCESSING CHAMBERS, APPARATUS, AND METHODS

(71) Applicant: Applied Materials, Inc., Santa Clara, CA (US)

(72) Inventors: Shu-Kwan LAU, Sunnyvale, CA (US); Aniketnitin PATIL, San Jose, CA (US); Martin Jeffrey SALINAS, San Jose, CA (US); Raja Murali DHAMODHARAN, Madurai (IN); Ala MORADIAN, Sunnyvale, CA (US); Zhepeng CONG, San Jose, CA (US)

(21) Appl. No.: 19/048,207

(22) Filed: Feb. 7, 2025

Related U.S. Application Data
(60) Provisional application No. 63/689,513, filed on Aug. 30, 2024.

(51) Int. Cl. H01L 21/67; C23C 16/455

(52) U.S. Cl. CPC H01L 21/67017; C23C 16/45508

(57) ABSTRACT

The present disclosure relates to gas injection for gas depletion and gas concentration adjustability, and related chamber kits, methods, and processing chambers. In one or more embodiments, a substrate processing chamber includes a chamber body at least partially defining an internal volume. A substrate support is disposed in the internal volume. The processing chamber further includes an injector operable to provide one or more process gases into a processing volume of the internal volume and a spatial injector operable to provide one or more first supplemental gases into the processing volume at a location radially inwardly of an outer edge of the substrate support.

### CROSS-REFERENCE TO RELATED APPLICATIONS

This application claims priority to U.S. Provisional Patent Application Ser. No. 63/689,513 filed on Aug. 30, 2024 the contents of which are incorporated herein by reference in their entirety.

### BACKGROUND

### Field

The present disclosure relates to gas injection for gas depletion and gas concentration adjustability, and related chamber kits, methods, and processing chambers.

### Description of the Related Art

Semiconductor substrates are processed for a wide variety of applications, including the fabrication of integrated devices and microdevices. One method of processing substrates includes depositing a material, such as a semiconductor material or a conductive material, on an upper surface of the substrate. For example, epitaxy is one deposition process that deposit films of various materials on a surface of a substrate in a processing chamber. During processing, various parameters can affect the uniformity of material deposited on the substrate.

Operations (such as epitaxial deposition operations) involve one or more processing gases to be heated in order to be activated (such as cracked). As process gases flow in chambers the process gases can deplete, which can limit adjustability of processing (e.g., deposition growth and selectivity). Flow velocity and temperature can affect depletion.

Therefore, a need exists for improved apparatuses and methods in semiconductor processing.

### SUMMARY

The present disclosure relates to gas injection for gas depletion and gas concentration adjustability, and related chamber kits, methods, and processing chambers.

In one or more embodiments, a substrate processing chamber includes a chamber body at least partially defining an internal volume. A substrate support is disposed in the internal volume. The processing chamber further includes an injector operable to provide one or more process gases into a processing volume of the internal volume and a spatial injector operable to provide one or more first supplemental gases into the processing volume at a location radially inwardly of an outer edge of the substrate support.

In one or more embodiments, a substrate processing chamber includes a chamber body at least partially defining an internal volume. A substrate support is disposed in the internal volume. The processing chamber further includes an injector operable to provide one or more process gases into a processing volume of the internal volume. A plate injector is disposed between the substrate support and a lid of the substrate processing chamber. The plate injector includes one or more openings operable to provide one or more supplemental gases into the processing volume at one or more locations disposed radially inwardly of an outer edge of the substrate support.

In one or more embodiments, a method of substrate processing includes heating a substrate positioned on a substrate support within an internal volume and flowing one or more process gases into a processing volume at a first location. The method further includes flowing one or more supplemental gases into the processing volume at one or more second locations radially inwardly of the first location and flowing the one or more process gases across the substrate. The method further includes flowing the one or more supplemental gases over the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a partial schematic side cross-sectional view of a processing chamber, according to one or more embodiments.

FIG. 2 is a partial schematic top view of the processing chamber including a cross-flow injector, a first spatial injector, and a second spatial injector.

FIG. 3 is a partial schematic side cross-sectional view of the processing chamber and the injectors shown in FIG. 2, according to one or more embodiments.

FIG. 4 is a graphical view showing precursor concentration profiles facilitated using the cross-flow injector, the first spatial injector, and the second spatial injector.

FIG. 5 is a partial schematic top view of the processing chamber with the first spatial injector and the second spatial injector fluidly connected to the same gas supply (such as the same flow ratio controller (FRC) as the cross-flow injector, according to one or more embodiments.

FIG. 6 is a partial schematic top view of the processing chamber with the first spatial injector and the second spatial injector respectively including a plurality of curved sections (such as ring-shaped sections), according to one or more embodiments.

FIG. 7 is a partial schematic top view of the processing chamber with the first spatial injector and the second spatial injector respectively including a plurality of mesh sections (such as intersecting sections), according to one or more embodiments.

FIG. 8 is a partial schematic side cross-sectional view of the processing chamber with the spatial injectors having upward injection and/or downward injection flow, according to one or more embodiments.

FIG. 9 is a partial schematic side cross-sectional view of the processing chamber with a spatial injector inserted at least partially into an opening of the injector 1015, according to one or more embodiments.

FIG. 10 is a partial schematic side cross-sectional view of the processing chamber with a spatial injector supported on the first liner, according to one or more embodiments.

FIG. 11 is a partial schematic side cross-sectional view of the processing chamber with a plate injector supported on the first liner, according to one or more embodiments.

FIG. 12 is a partial schematic side cross-sectional view of the processing chamber with an intersection injector provided through the first liner, according to one or more embodiments.

FIG. 13 is a schematic block diagram view of a method of substrate processing, according to one or more embodiments.

FIG. 14 is a schematic side cross-sectional view of a plate injector, according to one or more embodiments.

FIG. 15 is a schematic bottom view of the plate injector shown in FIG. 14, according to one or more embodiments.

FIG. 16 is a schematic enlarged side cross-sectional view of the plate injector disposed in the processing chamber 100, according to one or more embodiments.

FIG. 17 is a schematic partial side cross-sectional view of a plate injector disposed in the processing chamber, according to one or more embodiments.

FIG. 18 is a schematic top view of the second plate shown in FIG. 17, according to one or more embodiments.

FIG. 19 is a schematic partial perspective view of the second plate shown in FIG. 18, according to one or more embodiments.

FIG. 20 is a schematic top view of the first plate shown in FIG. 17, according to one or more embodiments.

FIG. 21 is a schematic partial perspective view of the first plate and the upper liner shown in FIG. 20, according to one or more embodiments.

FIG. 22 is a schematic partial enlarged top view of the first plate and the upper liner shown in FIG. 20, according to one or more embodiments.

FIG. 23 is a schematic partial perspective cross-sectional view of the first plate and the first liner shown in FIGS. 20-22, according to one or more embodiments.

FIG. 24 is a schematic partial side cross-sectional view of a plate injector disposed in the processing chamber, according to one or more embodiments.

FIG. 25 is a schematic perspective exploded view (from above) of the first plate and the second plate shown in FIG. 24, according to one or more embodiments.

FIG. 26 is a schematic partial side cross-sectional view of a plate injector, according to one or more embodiments.

FIG. 27 is a schematic perspective view of the plate injector shown in FIG. 26, according to one or more embodiments.

FIG. 28 is a schematic cross-sectional view, along Section 28-28 shown in FIG. 27, of the plate injector shown in FIG. 26, according to one or more embodiments.

FIG. 29 is a schematic partial side cross-sectional view of the plate injector shown in FIG. 26 disposed in the processing chamber, according to one or more embodiments.

FIG. 30 is a schematic partial perspective top view of the plate injector disposed in the processing chamber as shown in FIG. 29, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to spatial gas injection for gas depletion and gas concentration adjustability, and related processing chambers, apparatus, chamber kits, and methods. In one or more embodiments, an additional gas injection is used in a cross flow chamber that can be used to adjust gas depletion and gas concentration profiles of precursors along a direction from a leading edge to a trailing edge of a substrate. One or more spatial injectors are used in addition to a cross-flow injector, and the one or more spatial injectors can inject gas at location(s) that are radially inward of the cross-flow injector and/or above the substrate. In one or more embodiments, an apparatus adds gas at any point along a gas flow path. The apparatus can include an inject tube, inject mesh, and/or a gas flow plate (such as a showerhead). The apparatus can account for variations in flow and mixture splitting.

The disclosure contemplates that terms such as “couples,” “coupling,” “couple,” and “coupled” may include but are not limited to embedding, bonding, welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

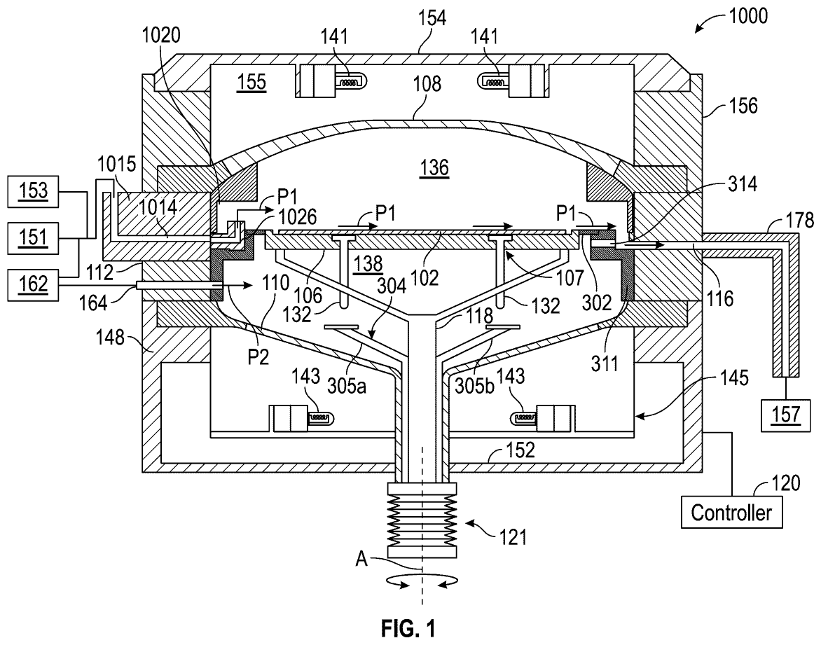

FIG. 1 is a partial schematic side cross-sectional view of a processing chamber 1000, according to one or more embodiments. The processing chamber 1000 is a deposition chamber. In one or more embodiments, the processing chamber 1000 is an epitaxial deposition chamber. In one or more embodiments, the processing chamber 1000 is utilized to grow an epitaxial film on a substrate 102. The processing chamber 1000 creates a cross-flow of precursors across a top surface of the substrate 102. The processing chamber 1000 is shown in a processing condition in FIG. 1.

The processing chamber 1000 includes an upper body 156, a lower body 148 disposed below the upper body 156, a flow module 112 disposed between the upper body 156 and the lower body 148. The upper body 156, the flow module 112, and the lower body 148 form a chamber body. An injector 1015 (e.g., the cross-flow injector) is disposed in between the flow module 112 and the upper body 156. Disposed within the chamber body is a substrate support 106, an upper plate 108 (such as an upper window and/or an upper dome), a lower plate 110 (such as a lower window and/or a lower dome), a plurality of upper heat sources 141, and a plurality of lower heat sources 143. The present disclosure contemplates that the upper plate 108 and/or the lower plate 110 can be in the shape of a dome or can be in another shape, such as flat, concave, or another contour.

The injector 1015 can be an inject ring, for example. As shown, a controller 120 is in communication with the processing chamber 1000 and is used to control processes and methods, such as the operations of the methods described herein. The present disclosure contemplates that each of the heat sources described herein can include one or more of: lamp(s), resistive heater(s), light emitting diode(s) (LEDs), and/or laser(s). The present disclosure contemplates that other heat sources can be used.

The substrate support 106 is disposed between the upper plate 108 and the lower plate 110. The substrate support 106 includes a support face that supports the substrate 102. The plurality of upper heat sources 141 are disposed between the upper window and a lid 154. The plurality of upper heat sources 141 form a portion of the upper heat source module 155. The lid 154 may include a plurality of sensors disposed therein or thereon for measuring the temperature within the processing chamber 1000. The plurality of lower heat sources 143 are disposed between the lower plate 110 and a floor 152. The plurality of lower heat sources 143 form a portion of a lower heat source module 145. In one or more embodiments, the upper plate 108 is an upper dome and is formed of an energy transmissive material, such as quartz. In one or more embodiments, the lower plate 110 is a lower dome and is formed of an energy transmissive material, such as quartz. A pre-heat ring 302 is disposed outwardly of the substrate support 106. A stop 304 includes a plurality of arms 305a, 305b that each include a lift pin stop on which at least one of the lift pins 132 can rest when the substrate support 106 is lowered (e.g., lowered from a process position to a transfer position).

The internal volume has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment for the shaft 118 and/or the substrate support 106.

The substrate support 106 may include lift pin perforations 107 disposed therein. The lift pin perforations 107 are sized to accommodate a lift pin 132 for lifting of the substrate 102 from the substrate support 106 either before or after a deposition process is performed.

The chamber body includes a first liner 1020 and a second liner 311. The second liner 311 is disposed below the first liner 1020. The pre-heat ring 302 is supported on a ledge of the second liner 311

In addition to the injector 1015 (which can define at least part of one or more sidewalls of the processing chamber 1000), one or more inject blocks 1026 are in fluid communication with the processing volume 136 of the internal volume. The one or more inject blocks 1026 are in fluid communication with one or more flow inlets (such as one or more flow gaps between the first liner 1020 and the second liner 311). The one or more inject blocks 1026 having one or more flow openings formed therein can be disposed in the one or more flow openings. The injector 1015 is fluidly connected to one or more process gas sources 151 and one or more cleaning gas sources 153. One or more gas inlets 1014 are formed in the injector 1015. The purge gas inlets 164 are fluidly connected to one or more purge gas sources 162. The one or more exhaust outlets 116 are fluidly connected to an exhaust pump 157. One or more process gases supplied using the one or more process gas sources 151 can include one or more reactive gases (such as one or more of silicon-containing, phosphorus-containing, and/or germanium-containing gases, and/or one or more carrier gases (such as one or more of nitrogen (N2) and/or hydrogen (H2)), and/or one or more etchant gases (such as one or more of hydrogen and/or chlorine (such as hydrochloric acid (HCl)). One or more purge gases supplied using the one or more purge gas sources 162 can include one or more inert gases (such as one or more of argon (Ar), helium (He), and/or nitrogen (N2)). One or more cleaning gases and/or etching gases supplied using the one or more cleaning gas sources 153 can include one or more of hydrogen and/or chlorine (such as hydrochloric acid (HCl)). In one or more embodiments, the one or more process gases include silicon hydrides (such as one or more silanes and/or one or more chlorinated silanes), germanium (such as germane (GeH4)), boron (such as diborane (B2H6)), and/or phosphine (PH3).

The one or more exhaust outlets 116 are further connected to or include an exhaust system 178. The exhaust system 178 fluidly connects the one or more exhaust outlets 116 and the exhaust pump 157. The exhaust system 178 can assist in the controlled deposition of a layer on the substrate 102. The exhaust system 178 is disposed on an opposite side of the processing chamber 1000 relative to the flow module 112.

During a deposition operation (e.g., an epitaxial growth operation), the one or more process gases P1 flow through the injector 1015 and into the processing volume 136 to flow horizontally over the substrate support 106 and the substrate 102 and to the one or more exhaust outlets 116. The one or more purge gases P2 are supplied from one or more purge gas sources 162 to the purge volume 138 through one or more purge gas inlets 164. The one or more purge gases P2 flow simultaneously with the flowing of the one or more process gases P1. The one or more process gases P1 are exhausted through exhaust gaps between the first liner 1020 and the second liner 311, and through the one or more exhaust outlets 116. The one or more purge gases P2 can be exhausted through the same exhaust gaps between the first liner 1020 and the second liner 311 or through exhaust opening(s) 314, and through the same one or more exhaust outlets 116 as the one or more process gases P1. The present disclosure contemplates that that one or more purge gases P2 can be separately exhausted through one or more second gas exhaust outlets that are separate from the one or more exhaust outlets 116.

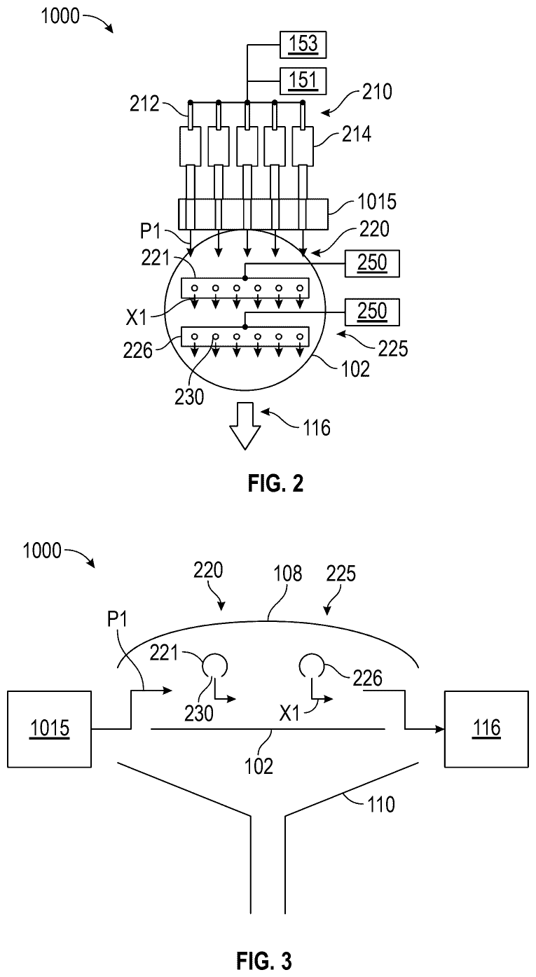

The injector 1015, sections of the cross-flow injector 210 (FIG. 2), and/or sections of the spatial injectors 220, 225 (FIG. 2) can be formed of a transparent material, such as a clear quartz, to allow the electromagnetic radiation to pass therethrough. Other materials, such as opaque materials, are contemplated as well. For example, the injector 1015, sections of the cross-flow injector 210 (FIG. 2), and/or sections of spatial injectors 220, 225 (FIG. 2) can be formed of an opaque material configured to absorb electromagnetic radiation to activate gases. The opaque material has an emissivity that is greater than or equal to 0.45 at 1,000 degrees Celsius. In one or more embodiments, the emissivity of the opaque material is within a range of 0.45 to 0.9, or higher, at 1,000 degrees Celsius. In one or more embodiments, the emissivity is within a range of 0.45 to 0.85, such as about 0.80. The opaque material has a thermal conductivity that is less than 10.0 W/m-K at a processing temperature. In one or more embodiments, the thermal conductivity of the opaque material is less than 5.0 W/m-K, such as less than 3.0 W/m-K. In one or more embodiments, the thermal conductivity of the opaque material is about 1.5. The opaque material includes silicon carbide (SIC), graphite coated with SiC, and/or opaque quartz (such as black quartz, grey quartz, and/or white quartz). In one or more embodiments, the opaque material is formed of SiC. In one or more embodiments, the SiC is pure SiC (e.g., having an atomic percentage of at least 99% for silicon and carbon) formed using chemical vapor deposition (CVD). It is believed that the pure SiC is resistant to process gases (e.g., corrosion resistant) and facilitates high absorption and emissivity. Other materials are contemplated for the injector 1015. For example, metal(s) (such as stainless steel and/or aluminum) and/or ceramic(s) can be used for the injector 1015, cross-flow injector 210 (FIG. 2), and/or spatial injectors 220, 225 (FIG. 2).

FIG. 2 is a partial schematic top view of the processing chamber 1000 including the injector 1015, according to one or more embodiments. The processing chamber 1000 further includes a cross-flow injector 210, a first spatial injector 220, and a second spatial injector 225. Two spatial injectors are shown, and other numbers of spatial injectors are contemplated. The respective spatial injectors can have individual flow rates, individual temperatures, and/or individual gas compositions.

The cross-flow injector 210 includes one or more flow inlets 212 fluidly connected to the one or more process gas sources 151, one or more cleaning gas sources 153, or a combination thereof. The one or more process gas sources 151, one or more cleaning gas sources 153, or a combination thereof supply one or more process gas P1 to the cross-flow injector 210. The one or more process gases P1 includes one or more reactive gases, one or more cleaning/etching gases, or combinations thereof. In one or more embodiments each of the one or more flow inlets 212 includes a valve 214. Each valve 214 controls the flow rate of the one or more process gases P1. In one or more embodiments, each valve 214 is independently controllable from one another. In one or more embodiments, each valve 214 can be independently controlled to be open or closed. When the valve 214 is open, the one or more process gases P1 are able to flow through the respective flow inlet 212. When the valve 214 is closed, the one or more process gases P1 are blocked from being able to flow through the respective flow inlet. In one or more embodiments, each valve 214 can be partially opened. When the valve 214 is partially opened the one or more process gases P1 are able to flow through the respective flow inlet 212, but the valve 214 decreases a flow rate of the one or more process gases P1 flowing through the valve 214 by providing a resistance to the flow of the one or more process gases P1. In one or more embodiments, the respective valves 214 are mass flow controllers (MFCs). The MFCs of the cross flow injector together can form a flow ratio controller. The flow ratio controller is used to control the ratio of different gases in the one or more process gases P1 that are flowed to different areas of the injector 1015.

The processing chamber 1000 further includes a first spatial injector 220 and a second spatial injector 225. The first spatial injector 220 includes a first spatial inlet 221. The second spatial injector 225 includes a second spatial inlet 226. The first spatial injector 220 and the second spatial injector 225 are fluidly connected to one or more supplemental gas sources 250 with one or more tube sections. The one or more supplemental gas sources 250 include one or more supplemental gases X1. The one or more supplemental gases X1 includes one or more reactive gases, one or more cleaning/etching gases, or combinations thereof. In one or more embodiments, the one or more supplemental gases X1 are the same as the one or more process gases P1. In one or more embodiments, the one or more supplemental gases X1 are different from the one or more process gases P1. In one or more embodiments, one or more supplemental gases X1 supplied to the first spatial inlet 221 is different from the one or more supplemental gases X1 supplied to the second spatial inlet 226. In one or more embodiments, the same one or more supplemental gases X1 are supplied to both the first spatial inlet 221 and the second spatial inlet 226. In one or more embodiments the first spatial inlet and the second spatial inlet are formed of a transparent quartz. In one or more embodiments, the first spatial injector 220 is offset from the second spatial injector 225 along a radial direction of the substrate support 106.

The first spatial injector 220 is disposed within the chamber body and is offset azimuthally from the cross-flow injector 210 at a first angle from about 30 degrees to about 150 degrees, such as about 90 degrees. The second spatial injector 225 is disposed within the chamber body offset azimuthally from the cross-flow injector 210 at a second angle from about 30 degrees to about 150 degrees, such as about 90 degrees. In one or more embodiments the first spatial inlet 221 and the second spatial inlet 226 extend through the first liner 1020. In one or more embodiments, the first spatial inlet 221 and the second spatial inlet 226 further extend over substrate 102. Both the first spatial inlet 221 and the second spatial inlet 226 include one or more openings 230. The one or more supplemental gases X1 flow from the one or more supplemental gas sources 250 through the first spatial inlet 221, the second spatial inlet 226, or a combination thereof. The first spatial inlet 221 and the second spatial inlet 226 are operable to provide the one or more supplemental gases X1 at a location radially inwardly of an outer edge of the substrate support 106. The one or more supplemental gases X1 are flowed out of the one or more openings 230 and over the substrate 102. In one or more embodiments, the one or more openings 230 are positioned above the substrate 102 so that the one or more supplemental gases X1 flow out of the first spatial inlet 221, the second spatial inlet 226, or a combination thereof, over the substrate 102. In one or more embodiments, the first spatial injector 220 and a second spatial injector 225 further include one or more valves 214.

The cross-flow injector 210 flows the one or more process gases P1 horizontally across the substrate 102 and towards the one or more exhaust outlets 116. In one or more embodiments, as the one or more process gases P1 flow across the substrate 102 towards the one or more exhaust outlets 116 a concentration of the one or more reactive gases, the one or more cleaning/etching gases, or combinations thereof, within the one or more process gases P1 may decrease. The one or more supplemental gases X1 are supplied over the substrate along a flow path of the one or more process gases P1. In one or more embodiments, the one or more supplemental gases X1 is mixed into the one or more process gases P1 as the one or more process gases P1 flow across the substrate. In one or more embodiments, the one or more supplemental gases X1 increases a concentration of the one or more reactive gases, the one or more cleaning/etching gases, or combinations thereof, within the one or more process gases P1 as the one or more process gases P1 flow across the substrate 102. The one or more supplemental gases X1 flows with the one or more process gases P1 along a flow path of the one or more process gases P1, where both the one or more supplemental gases X1 and the one or more process gases P1 are exhausted through the one or more exhaust outlets 116.

FIG. 3 is a partial schematic side cross-sectional view of the processing chamber 1000 and the spatial injectors 220, 225 shown in FIG. 2, according to one or more embodiments. The first spatial inlet 221 and the second spatial inlet 226 include one or more openings 230 formed on the bottom of the first spatial inlet 221 and the second spatial inlet 226 respectively. During a processing operation, the one or more supplemental gases X1 flow into the first spatial inlet 221, the second spatial inlet 226, or a combination thereof. The one or more supplemental gases X1 then proceed to flow out of the one or more openings 230 over the substrate. In one or more embodiments, the one or more processing gases P1 are flowed across the substrate simultaneously to the one of more supplemental gasses X1 being flowed through the one or more openings. The one or more supplemental gases X1 flows with the one or more process gases P1 along a flow path of the one or more process gases P1, where both the one or more supplemental gases X1 and the one or more process gases P1 are exhausted through the one or more exhaust outlets 116.

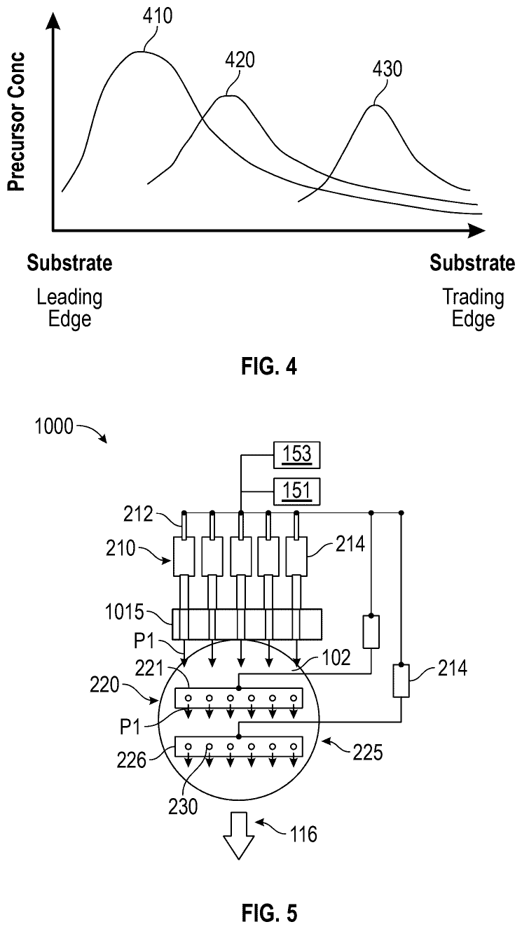

FIG. 4 is a graphical view showing precursor concentration profiles facilitated using the cross-flow injector, the first spatial injector, and the second spatial injector, according to one or more embodiments.

A process gas concentration profile 410 shows the concentration of the one or more process gases P1 (e.g., a primary gas flow) as the one or more process gases P1 flow across the substrate 102. The process gas concentration profile 410 shows that the one or more process gases P1 has a high concentration at the leading edge of the substrate, and the concentration of the one or more process gases P1 lowers while flowing across the substrate 102. A first supplemental gas profile 420 shows the concentration of one or more supplemental gases X1 from the first spatial injector 220. A second supplemental gas profile 430 shows the concentration of one or more supplemental gases X1 from the second spatial injector 225. The concentration of the one or more supplemental gases X1 is highest at the location of the spatial injectors 220, 225. The concentration of the one or more supplemental gases X1 decreases as the one or more supplemental gases X1 flow away from the spatial injectors 220, 225.

FIG. 5 is a partial schematic top view of the processing chamber 1000 with the first spatial injector 220 and the second spatial injector 225 fluidly connected to the same gas supply (such as the same flow ratio controller (FRC) as the cross-flow injector 210, according to one or more embodiments. The present disclosure contemplates that the cross-flow injector 210 can be referred to as a primary injector.

In one or more embodiments, the first spatial injector 220 and the second spatial injector 225 are fluidly connected to the one or more process gas sources 151, one or more cleaning gas sources 153, or a combination thereof. The one or more process gas sources 151 one or more cleaning gas sources 153, or a combination thereof supply one or more process gas P1 to the cross-flow injector 210, the first spatial injector 220, the second spatial injector, or a combination thereof. In one or more embodiments, the first spatial injector 220 and the second spatial injector further include a valve 214 (such as a mass flow controller (MFC)). The valves 214 respectively control the flow rates and/or flow ratios of the one or more process gases P1. In one or more embodiments, each valve 214 is independently controllable from one another. In one or more embodiments, the one or more process gases P1 flow from the cross-flow injector 210 horizontally across the substrate 102 and towards the one or more exhaust outlets 116. Simultaneously, the one or process gases P1 flow through the first spatial injector 220, the second spatial injector 225, or a combination thereof. The one or more process gases P1 proceed to flow into the first spatial inlet 221 and/or the second spatial inlet 226. The one or more process gases P1 flow out of the one or more openings 230 and over the substrate 102. In one or more embodiments, the one or more openings 230 are positioned above the substrate 102 so that the one or more process gases P1 flow out of the first spatial inlet 221, the second spatial inlet 226, or a combination thereof, over the substrate 102. The spatial injectors 220, 225 respectively include one or more conduits (such as one or more tubes including the tube sections). The spatial injectors 220, 225 can have a curved cross section, such as a circular cross section. Other cross sections, such as rectangular cross sections, can be used.

In one or more embodiments, the respective valves 214 are mass flow controllers (MFCs). The MFCs of the cross-flow injector 210 together form a first flow ratio controller (FRC). The first FRC is used to control the ratio of different gases in the one or more process gases P1 that are flowed to different areas of the injector 1015, which can correspond to different processing zones of the substrate. The valve 214 of the first spatial injector 220 and the valve 214 of the second spatial injector 225 can be an MFC. The MFC of the first spatial injector 220 and the MFC of the second spatial injector 225 together form a second FRC. The second FRC is used to control the ratio of different gases in the one or more process gases P1 that are flowed to different areas of the substrate 102 through the first spatial injector 220 and the second spatial injector 225.

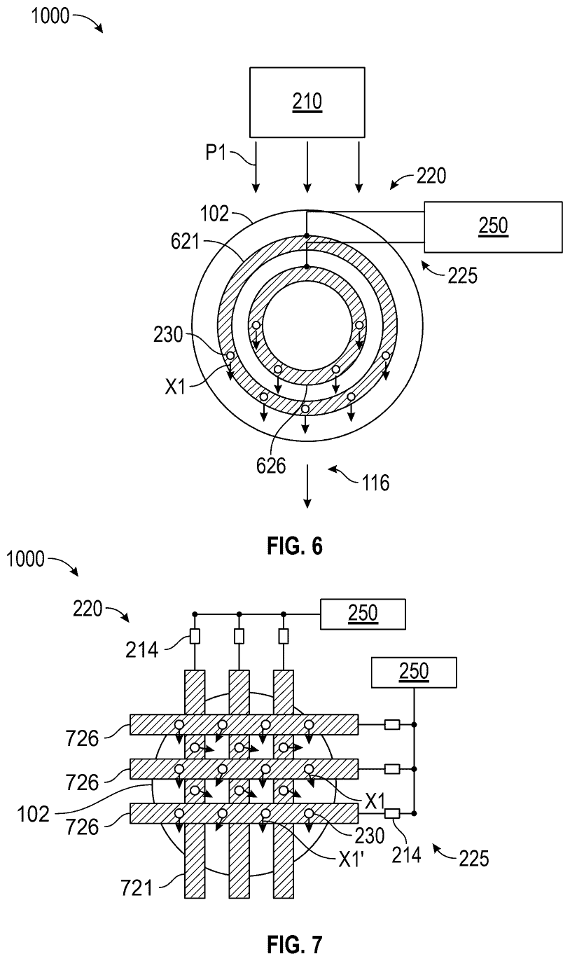

FIG. 6 is a partial schematic top view of the processing chamber 1000 with the first spatial injector 220 and the second spatial injector 225 respectively including a plurality of curved sections (such as ring-shaped sections), according to one or more embodiments.

The processing chamber 1000 incudes the first spatial injector 220 and a second spatial injector 225. In one or more embodiments, the first spatial injector 220 includes a first curved inlet 621. The second spatial injector 225 includes a second curved inlet 626. The first spatial injector 220 and the second spatial injector 225 are fluidly connected to one or more supplemental gas sources 250. The one or more supplemental gas sources 250 include one or more supplemental gases X1. In one or more embodiments, the first curved inlet 621 is a ring having an inner diameter. The second curved inlet 626 is disposed within the inner diameter of the first curved inlet 621. In one or more embodiments, the first curved inlet 621 is axially aligned with the second curved inlet 626. In one or more embodiments the first curved inlet 621, the second curved inlet 626, and the substrate 102 are all concentric around the same axis.

The one or more supplemental gases X1 flow from the one or more supplemental gas sources 250 through the first curved inlet 621, the second curved inlet 626, or a combination thereof. The one or more supplemental gases X1 are flowed out of the one or more openings 230 and over the substrate 102. In one or more embodiments, the one or more openings 230 are positioned above the substrate 102 so that the one or more supplemental gases X1 flow out of the first curved inlet 621, the second curved inlet 626, or a combination thereof, over the substrate 102. In one or more embodiments, the first spatial injector 220 and a second spatial injector 225 further include one or more valves 214. In one or more embodiments, the first curved inlet 621 and/or the second curved inlet 626 are an inner flow opening of a conduit (such as a tube). In one or more embodiments, the first curved inlet 621 and/or the second curved inlet 626 are a flow opening (such as a channel) formed in a plate and/or between a plurality of plates, such as to form a showerhead.

FIG. 7 is a partial schematic top view of the processing chamber with the first spatial injector 220 and the second spatial injector 225 respectively including a plurality of mesh sections (such as intersecting sections), according to one or more embodiments.

The processing chamber 1000 incudes the first spatial injector 220 and a second spatial injector 225. In one or more embodiments, the first spatial injector 220 includes a first plurality of inlets 721. The second spatial injector 225 includes a second plurality of inlets 726. The first spatial injector 220 and the second spatial injector 225 are fluidly connected to one or more supplemental gas sources 250. The one or more supplemental gas sources 250 include one or more supplemental gases X1. In one or more embodiments, the first plurality of inlets 721 extend across the substrate 102 in a first direction. The second plurality of inlets 726 extend across the substrate in a second direction. In one or more embodiments the first plurality of inlets 721 is about perpendicular to the second plurality of inlets 726. In one or more embodiments the first plurality of inlets 721 and the second plurality of inlets 726 overlap with one another to form a mesh. The one or more supplemental gases X1 flow from the one or more supplemental gas sources 250 through one or more inlets of the first plurality of inlets 721. In one or more embodiments, one or more supplemental gases flow from the one or more supplemental gas sources 250 through one or more inlets of the second plurality of inlets 726. In one or more embodiments the one or more supplemental gases X1 supplied to the first plurality of inlets 721 is different from the one of more supplemental gases X1′ supplied to the second plurality of inlets 726. In one or more embodiments, the one or more supplemental gases X1 supplied to the first plurality of inlets 721 is the same as the one of more supplemental gases X1′ supplied to the second plurality of inlets 726. The one or more supplemental gases X1, X1′ are flowed out of the one or more openings 230 and over the substrate 102. In one or more embodiments, the one or more openings 230 are positioned above the substrate 102 so that the one or more supplemental gases flow out of the first plurality of inlets 721, the second plurality of inlets 726, or a combination thereof, over the substrate 102. In one or more embodiments, the first spatial injector 220 and a second spatial injector 225 further include one or more valves 214. In one or more embodiments, first plurality of inlets 721 and/or the second plurality of inlets 726 are an inner flow opening of a conduit (such as a tube). In one or more embodiments, the first plurality of inlets 721 and/or the second plurality of inlets 726 are a flow opening (such as a channel) formed in a plate and/or between a plurality of plates, such as to form a showerhead.

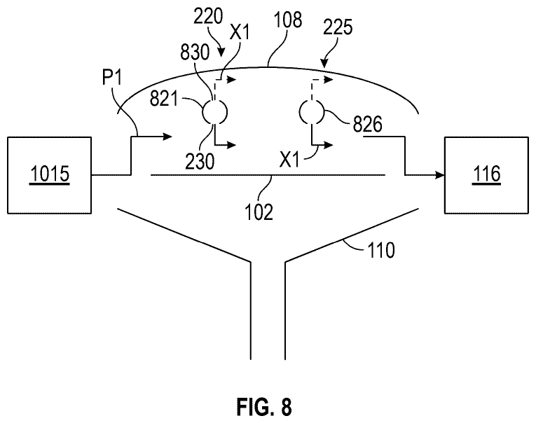

FIG. 8 is a partial schematic side cross-sectional view of the processing chamber 1000 with the spatial injectors 220, 225 having upward injection and/or downward injection flow, according to one or more embodiments.

In one or more embodiments, the processing chamber 1000 includes a first spatial injector 220 having a first spatial inlet 821 and a second spatial injector 225 having a second spatial inlet 826. The first spatial inlet 821 and the second spatial inlet 826 include one or more openings 230 formed on the bottom of the first spatial inlet 821 and the second spatial inlet 826 respectively. In one or more embodiments, the first spatial inlet 821 and the second spatial inlet 826 further include one or more upper openings 830 formed on the top of the first spatial inlet 821 and the second spatial inlet 826 respectively. During a processing operation, the one or more supplemental gases X1 flow into the first spatial inlet 221, the second spatial inlet 226, or a combination thereof. The one or more supplemental gases X1 then proceed to flow out of the one or more openings 230 over the substrate. In one or more embodiments, the one or more supplemental gases proceed to flow out of the one or more upper openings 830 into the processing volume 136. The one or more supplemental gases X1 can help increase the concentration of the one or more reactive gases, the one or more cleaning/etching gases, or combinations thereof, within the processing volume 136. In one or more embodiments, the one or more processing gases P1 are flowed across the substrate simultaneously to the one of more supplemental gasses X1 being flowed through the one or more openings. The one or more supplemental gases X1 flows with the one or more process gases P1 along a flow path of the one or more process gases P1, where both the one or more supplemental gases X1 and the one or more process gases P1 are exhausted through the one or more exhaust outlets 116.

The one or more supplemental gases X1 can push the one or more process gases P1 downward toward the substrate 102 and/or the one or more supplemental gases X1 can prevent the one or more process gases from flowing along an inner surface of the upper plate 108 (such as to reduce or prevent coating of the upper plate 108).

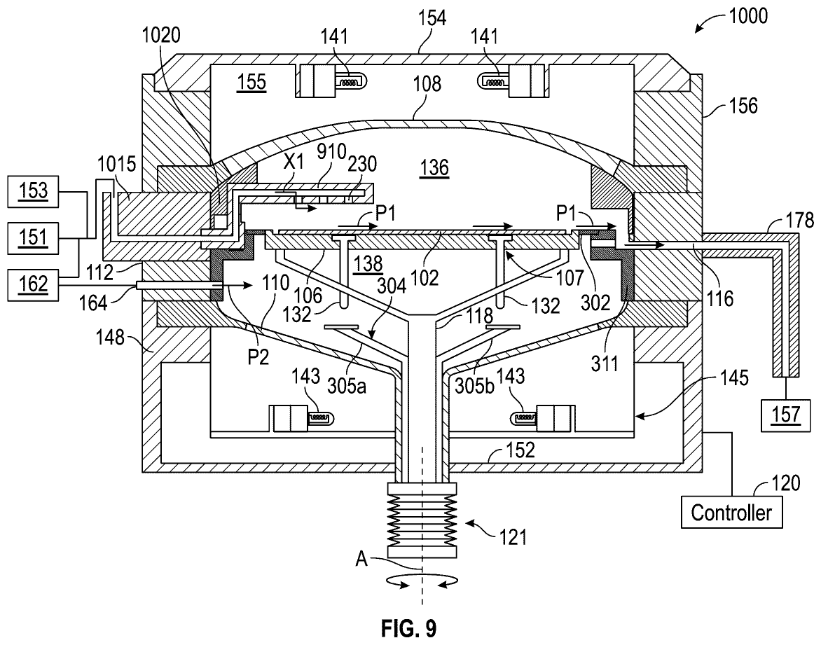

FIG. 9 is a partial schematic side cross-sectional view of the processing chamber 1000 with a cross flow spatial injector 910 inserted at least partially into an opening of the injector 1015, according to one or more embodiments.

In one or more embodiments, the inject block 1026 is omitted, and the cross flow spatial injector 910 is disposed in place of the inject block 1026. In one more embodiments, a flow inlet to the cross flow spatial injector 910 is disposed azimuthally outwardly or azimuthally inwardly of the inject block 1026. A plurality of inject blocks 1026 can be used, and a flow inlet to the spatial injector can be disposed azimuthally between inject blocks 1026.

The cross flow spatial injector 910 extends over at least a portion of the substrate 102. The cross flow spatial injector 910 includes one or more openings 230. During a processing operation one or more supplemental gases X1 flow from the injector 1015 through the cross flow spatial injector 910. The one or more supplemental gases X1 proceed to flow through the openings 230 of the cross flow spatial injector 910 disposed over the substrate 102. After the one or more supplemental gases X1 flow out of the openings 230, the one or more supplemental gases X1 flow across the substrate to the one or more exhaust outlets 116. In one or more embodiments, the one or more supplemental gases X1 flow simultaneously with the one or more process gases P1 flowing through the inject block(s) 1026.

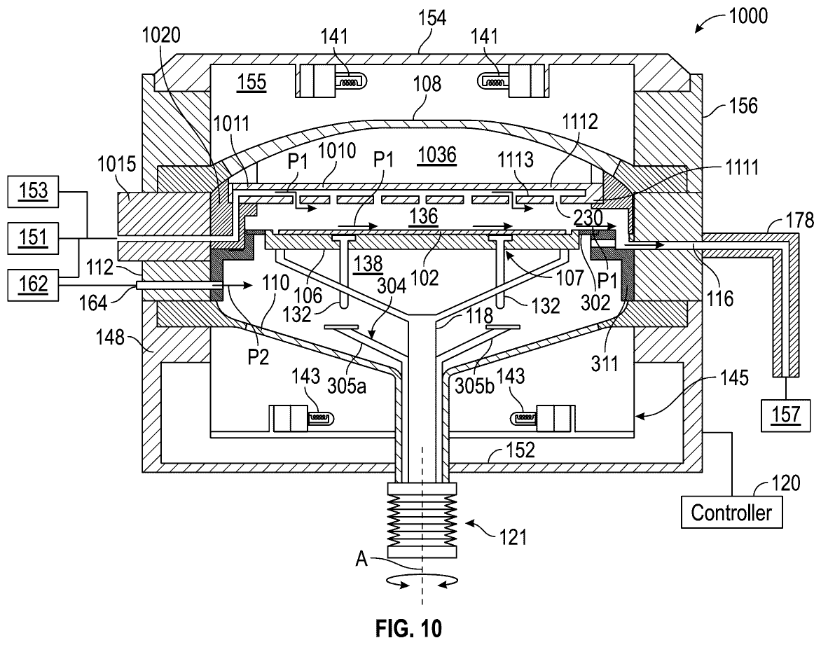

FIG. 10 is a partial schematic side cross-sectional view of the processing chamber 1000 with a plate injector 1010 supported on the first liner 1020, according to one or more embodiments.

In one or more embodiments, the inject block 1026 is omitted, and the plate injector 1010 is disposed in place of the inject block 1026. In one more embodiments, a flow inlet to the plate injector 1010 is disposed azimuthally outwardly or azimuthally inwardly of the inject block 1026. A plurality of inject blocks 1026 can be used, and a flow inlet to the plate injector 1010 can be disposed azimuthally between inject blocks 1026. The plate injector 1010 includes a first face 1111, a second face 1112, one or more channels 1113, and one or more openings 230. The one or more channels 1113 are disposed between the first face 1111 and the second face 1112. The one or more channels 1113 are fluidly connected to the injector 1015. One or more openings 230 are formed in the first face 1111. The one or more openings 230 extend through the first face 1111 and fluidly connect to the one or more channels 1113. In one or more embodiments, the plate injector 1010 extends over the substrate 102 and at least partially defines the processing volume 136.

The one or more openings 230 are formed over the substrate 102. During a processing operation one or more process gases P1 flow from the injector 1015 through the one or more channels 1113 of the plate injector 1010. The one or more process gases P1 proceed to flow through the openings 230 of the plate injector 1010 disposed over the substrate 102. After the one or more process gases P1 flow out of the openings 230, the one or more process gases P1 flow across the substrate to the one or more exhaust outlets 116. The plate injector 1010 can be formed of a single plate or a plurality of plates. For example, the plate injector 1010 can include a first plate that includes the openings 230 and the one or more channels 1113, and a solid second plate can be fused or welded to the first plate to cover the one or more channels 1113.

The plate injector 1010 can be disposed to separate the processing volume 136 from a remote volume 1036 between the upper plate 108 and the plate injector 1010.

The plate injector 1010 can include a tab extension 1011 (such as an extension section). The tab extension 1011 can extend into an opening (such as a recess) of the first liner 1020 align and/or assist sealing of the plate injector 1010 to the first liner 1020. For example, the tab extension 1011 can function as an interlocking mechanism.

As described, gas(es) such as process gas(es) can flow into the injectors (such as the plate injector 1010) described herein on an inject side of the processing chamber 1000 that is opposite of an exhaust side of the processing chamber 1000, and/or the gas(es) can flow into the injectors on the exhaust side of the processing chamber 1000. The present disclosure contemplates the gas(es) can flow into the injectors on an intersection side (which is azimuthally between the inject side and the exhaust side) of the processing chamber 1000, as shown for example in FIG. 11.

FIG. 11 is a partial schematic side cross-sectional view of the processing chamber 1000 with a plate injector 1010 supported on the first liner 1020, according to one or more embodiments.

The plate injector 1010 in FIG. 11 is positioned at a supplemental position, which can be azimuthally spaced about 60-120 degrees (such as 90 degrees) from the view shown in FIGS. 1 and 10, for example. The one or more channels 1113 of the plate injector 1010 are fluidly connected to an intersection injector 1125. The intersection injector 1125 is fluidly connected to one or more supplemental gas sources 250. During a processing operation one or more supplemental gases X1 flow from the intersection injector 1125 through the one or more channels 1113 of the plate injector 1010. The one or more channels 1113 of the plate injector 1010 are disposed at a non-zero angle (such as 10 degrees to 170 degrees, for example about 90 degrees) relative to a flow opening 1016 of the injector 1015. The one or more supplemental gases X1 proceed to flow through the openings 230 of the plate injector 1010 disposed over the substrate 102. After the one or more supplemental gases X1 flow out of the openings 230, the one or more supplemental gases X1 flow across the substrate 102 with the one or more process gases P1 to the one or more exhaust outlets 116. The supplemental gases X1 can flow into the plate injector 1010 at an offset azimuthal angle relative to the primary flow of the one or more process gases P1. The offset azimuthal angle can be similar to the offset azimuthal angle between the one or more process gases P1 and the one or more supplemental gases X1 that is shown in FIGS. 2 and 3.

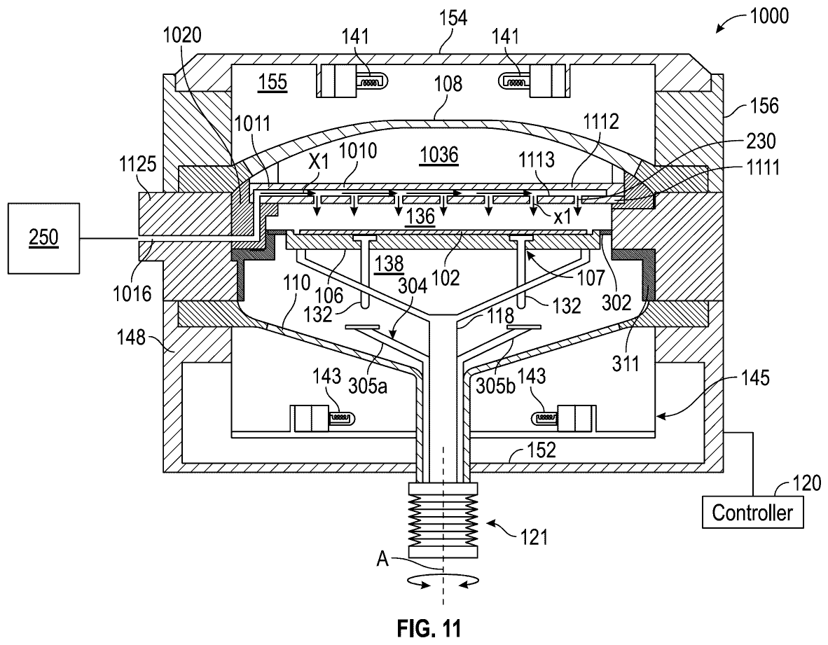

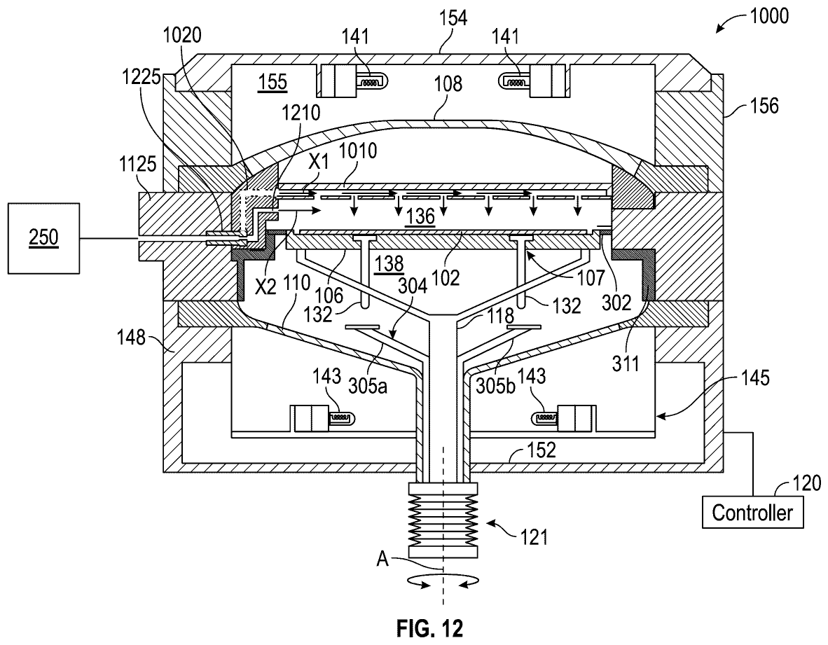

FIG. 12 is a partial schematic side cross-sectional view of the processing chamber 1000 with an intersection injector 1125 provided through the first liner 1020, according to one or more embodiments.

The intersection injector 1125 in FIG. 11 is positioned at an intersection injection position, which can be azimuthally spaced about 60-120 degrees (such as 90 degrees) from the view shown in FIGS. 1 and 10, for example. An intersection flow conduit 1225 (such as an intersection flow tube) can be disposed in the intersection injector 1115 and the first liner 1020. The intersection flow conduit 1225 flows one or more second supplemental gases X2 therethrough, and into a supplemental opening 1210.

The intersection flow conduit 1225 is between the intersection injector 1125 and the first liner 1020. The intersection flow conduit 1225 can separate the flow second supplemental gases X2 through the first liner 1020 from the flow of first supplemental gases X1 through the plate injector 1010. The intersection injection of the second supplemental gases X2 in FIG. 12 is positioned at an intersection injection position, which can be azimuthally spaced about 0-20 degrees (such as 5 degrees) from the first supplemental gases X1, for example.

In one or more embodiments, the supplemental opening 1210 is formed in the first liner 1020. The supplemental opening 1210 is disposed between the plate injector 1010 and the substrate 102. The supplemental opening 1210 is offset (e.g., azimuthally spaced) from the cross-flow injector 210 by about 60-120 degrees (such as 90 degrees). During a processing operation one or more second supplemental gases X2 flow from the intersection injector 1125 through the supplemental opening 1210. After the one or more second supplemental gases X2 flow out of the supplemental opening 1210, the one or more second supplemental gases X2 flow across the substrate 102 with the one or more process gases P1 to the one or more exhaust outlets 116. In one or more embodiments, the one or more second supplemental gases X2 and the one or more first supplemental gases X1 are flowed through the supplemental opening 1210 and the plate injector 1010 simultaneously.

The present disclosure contemplates that the intersection flow conduit 1225 can be a valve that switches flow between the supplemental opening 1210 and the plate injector 1010. For example, when the intersection flow conduit 1225 is in a first position, the one or more supplemental gases X1 can flow through the plate injector 1010 as described in FIG. 11, and the one or more supplemental gases X1 are prevented from flowing through the supplemental opening 1210. When the intersection flow conduit 1225 is in a second position, the one or more supplemental gases X1 flow through the supplemental opening 1210, and the one or more supplemental gases X1 are prevented from flowing through the plate injector 1010. The intersection flow conduit 1225 can control the flow rate one or more supplemental gases X1 to the plate injector 1010, supplemental opening 1210, or a combination thereof.

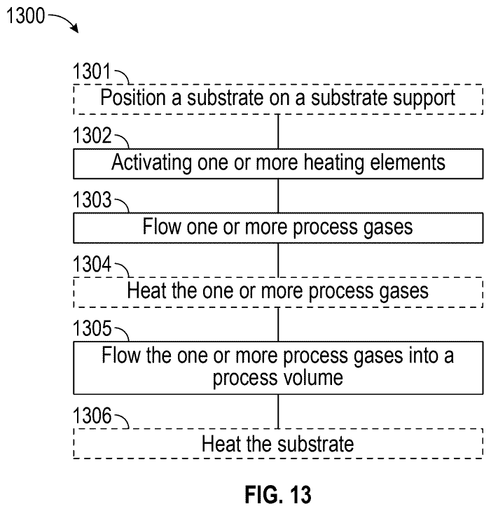

FIG. 13 is a schematic block diagram view of a method 1300 of substrate processing, according to one or more embodiments. In one or more embodiments, the method 1300 is performed using one or more components of the processing chamber 1000 described herein.

Optional operation 1301 of method 1300 includes positioning a substrate on a substrate support in a processing volume of a processing chamber. In one or more embodiments, the positioning includes moving a substrate support and/or a plurality of lift pins relative to each other to land the substrate on the substrate support.

Operation 1302 of the method 1300 includes activating one or more heating elements. In one or more embodiments, the activated heating elements emit electromagnetic radiation. In one or more embodiment, the one or more heating elements are resistive heaters.

Operation 1303 of the method 1300 includes flowing one or more process gases from one or more process gas sources to an injector. The one or more process gases can include one or more reactive gases (such as one or more of silicon-containing, phosphorus-containing, and/or germanium-containing gases, one or more carrier gases (such as one or more of nitrogen (N₂) and/or hydrogen (H2)), and/or one or more etchant gases (such as one or more of hydrogen and/or chlorine (such as hydrochloric acid (HCl)). In one or more embodiments one or more supplemental gases are flowed to one or more supplemental injectors simultaneously to the one or more process gases being flowed. The present disclosure also contemplates that the one or more supplemental gases and the one or more process gases can flow sequentially.

The one or more supplemental gases can include one or more reactive gases (such as one or more of silicon-containing, phosphorus-containing, and/or germanium-containing gases, one or more purge gases and/or carrier gases (such as one or more of nitrogen (N₂) and/or hydrogen (H2)), and/or one or more etchant gases (such as one or more of hydrogen and/or chlorine (such as hydrochloric acid (HCl)). In one or more embodiments the injector includes the injector 1015, the cross flow spatial injector 910, the plate injector 1010, or combinations thereof. In one or more embodiments, the one or more supplemental injectors include the first spatial injector 220, the second spatial injector 225, the plate injector 1010, the intersection injector 1125, or combinations thereof. In one or more embodiments the one or more process gases include the one or more process gases P1. In one or more embodiments the one or more supplemental gases include the one or more process gases P1, the one or more supplemental gases X1, the one or more supplemental gases X2, or a combination thereof.

Optional operation 1304 of the method 1300 includes heating the one or more process gases of operation 1303. In one or more embodiments, the one or more process gases are heated by exposing the one or more process gases to the electromagnetic radiation of operation 1302. In one or more embodiments the one or more process gases are heated using resistive heaters. In one or more embodiments, the one or more supplemental gases are heated simultaneously to the one or more process gases being heated.

Operation 1305 of the method 1300 includes flowing the one or more process gases over the substrate. The one or more process gases flow from the injector into the processing volume. The one or more process gases flow across the substrate while within the processing volume from the injector to one or more gas exhausts disposed opposite of the injector. In one or more embodiments, the one or more supplemental gases are flowed into the processing volume simultaneously to the one or more processing gases. The one or more supplemental gases are flowed from the one or more supplemental injectors. In one or more embodiments the one or more supplemental injectors are disposed above the substrate. In one or more embodiments, the supplemental injectors are positioned at a supplemental injector position, which can be azimuthally spaced about 60-120 degrees (such as 90 degrees) from the injector, for example.

Optional operation 1306 includes heating the substrate to a substrate temperature. In one or more embodiments, the substrate temperature is less than 550 degrees Celsius, such as less than 500 degrees Celsius. In one or more embodiments, the substrate temperature is 450 degrees Celsius or less, such as 400 degrees Celsius or less, for example 350 degrees Celsius. Other temperatures-such as temperatures within a range of 0 degrees Celsius to 1,500 degrees Celsius, are contemplated.

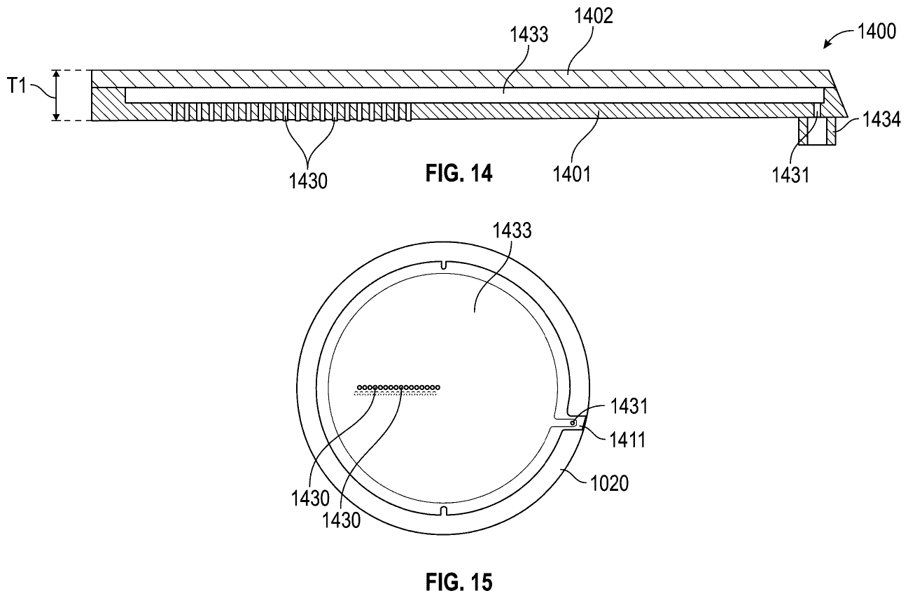

FIG. 14 is a schematic side cross-sectional view of a plate injector 1400, according to one or more embodiments.

The plate injector 1400 includes one or more plates. In one or more embodiments, the plate injector 1400 includes a first plate 1401 (such as a gas distribution plate) and a second plate 1402 (such as a cover plate) coupled (such as bonded, welded, and/or fused) to the first plate 1401.

FIG. 15 is a schematic bottom view of the plate injector 1400 shown in FIG. 14, according to one or more embodiments.

FIGS. 14 and 15 are now described together. The plate injector 1400 includes a plurality of flow openings 1430 disposed on one side of a center of the plate injector 1400. The flow openings are positioned along radial positions between the center and an edge of the plate injector 1400. A single row of flow openings 1430 are shown in solid FIG. 15. The present disclosure contemplates that multiple rows of flow openings 1430 may be used (as shown in ghost). The multiple rows of flow openings 1430 can be aligned or can be staggered (as shown in FIG. 15). The flow openings 1430 can vary with respect to size, position, shape, and/or arrangement layout. In one or more embodiments, the flow openings 1430 have a size. In one or more embodiments, the size is a diameter. In one or more embodiments, the size is a ratio of a thickness T1 of the plate injector 1400. In one or more embodiments, the ratio is 0.3 or less, such as 0.2 or less. In one or more embodiments, the ratio is 0.1 or less. In one or more embodiments, the thickness T1 is within a range of 3 mm to 8 mm, such as 4.5 mm to 6.5 mm. The size of the flow openings 1430 can vary. For example, the size can have an increasing gradient along a radially outward direction or along a radially inward direction.

The flow openings 1430 can be disposed along linear patterns (as shown in FIG. 15), or can be disposed along other shape patterns. For example, the shape pattern can be a polygon (such as a hexagon such that the arranged flow openings 1430 form a honeycomb shape).

The plate injector 1400 includes one or more inlet openings 1431 on an opposite side of the center relative to the flow openings 1430 (which can function as outlet openings). The inlet opening(s) 1431 and the flow openings 1430 are in fluid communication with one or more flow channels 1433. An extension 1434 is coupled (e.g., welded, such as fillet welded) to the first plate 1401. The extension 1434 includes one or more openings in fluid communication with the inlet opening(s) 1431. In one or more embodiments, the first and second plates 1401, 1402 are transparent (such as formed of transparent quartz) and the extension 1434 is opaque (such as formed of opaque quartz, silicon carbide (SiC), and/or graphite coated with SiC). In one or more embodiments, the extension 1434 is a rim, such as a hollow sleeve. A tab extension 1411 of the plate injector 1400 extends into an opening of the first liner 1020.

The present disclosure contemplates that a variety of numbers of plates can be used for the various plate injectors described herein. For example, the plate injector 1400 can be a single plate that is machined to include the openings 1430, 1431. As another example, the plate injector 1400 can be made up of three or more plates.

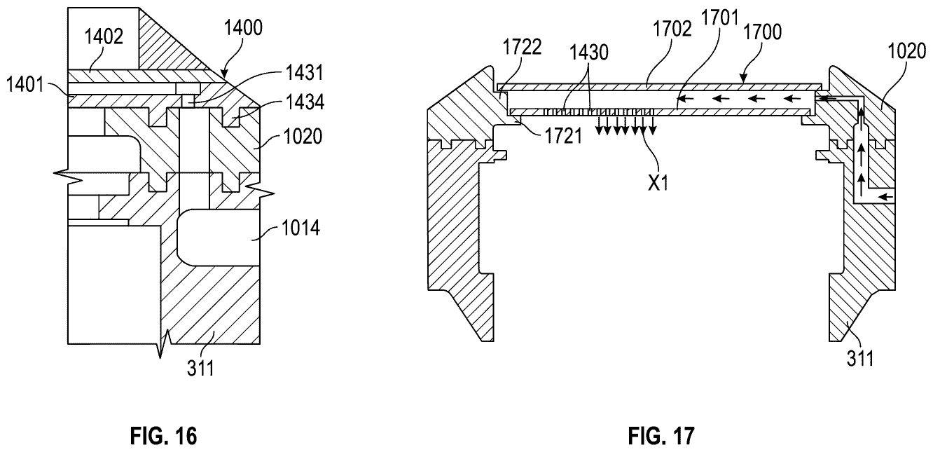

FIG. 16 is a schematic enlarged side cross-sectional view of the plate injector 1400 disposed in the processing chamber 100, according to one or more embodiments.

The one or more gas inlets 1014 are disposed at least partially in the second liner 311. The extension 1434 of the plate injector 1400 extends at least partially into one or more openings (e.g., recess(es)) of the first liner 1020. The first liner 1020 can similarly include an extension 1021 that extends at least partially into one or more openings (e.g., recess(es)) of the second liner 311. The extension 1434 and/or the tab extension 1411 can be used to locate (e.g., align) and/or lock the plate injector 1400 relative to the first liner 1020.

FIG. 17 is a schematic partial side cross-sectional view of a plate injector 1700 disposed in the processing chamber 1000, according to one or more embodiments.

The plate injector 1700 includes a first plate 1701 and a second plate 1702 spaced from the first plate 1701. The first plate 1701 is supported by one or more first ledges 1721 (e.g., lower ledge(s)) of the first liner 1020, and the second plate 1702 is supported by one or more second ledges 1722 (e.g., upper ledge(s)) of the first liner 1020.

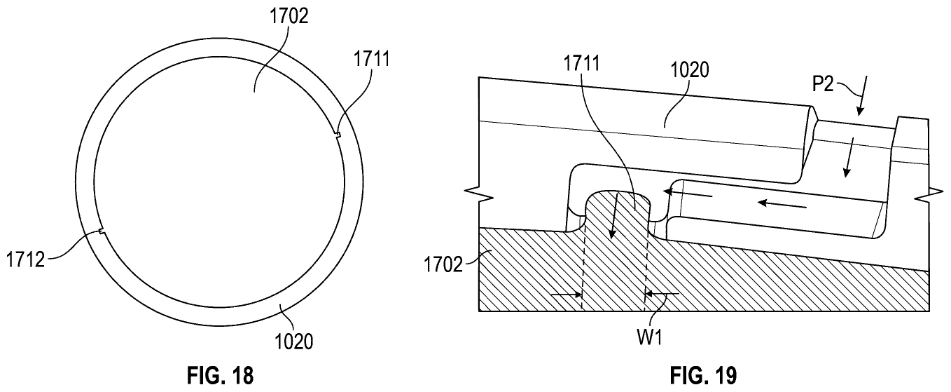

FIG. 18 is a schematic top view of the second plate 1702 shown in FIG. 17, according to one or more embodiments.

The second plate 1702 includes a plurality of tab extensions 1711, 1712 that extend radially outwardly and into the first liner 1020.

FIG. 19 is a schematic partial perspective view of the second plate 1702 shown in FIG. 18, according to one or more embodiments.

The tab extensions 1711, 1712 respectively extend into a channel path formed in the first liner 1020. The channel path of one tab extension 1711 provides an inlet for one or more purge gases P2, and the channel path of another tab extension 1712 provides an outlet for the one or more purge gases P2. A width W1 of the respective tab extensions 1711, 1712 is within a range of 2.5 mm to 7.5 mm, such as about 5.0 mm.

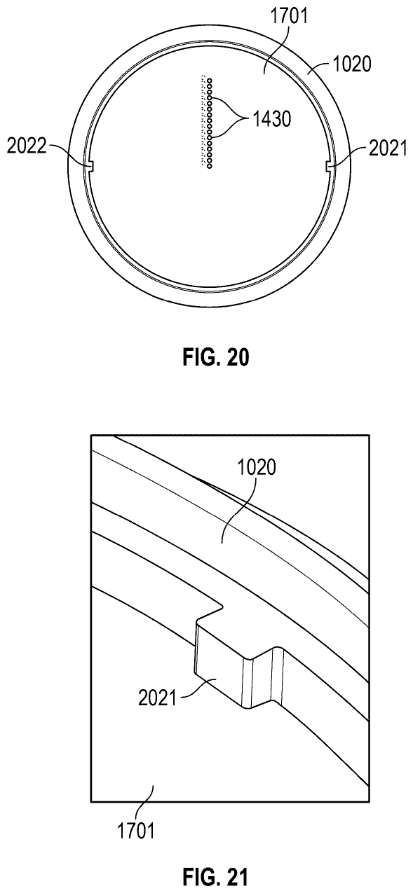

FIG. 20 is a schematic top view of the first plate 1701 shown in FIG. 17, according to one or more embodiments.

FIG. 21 is a schematic partial perspective view of the first plate 1701 and the first liner 1020 shown in FIG. 20, according to one or more embodiments.

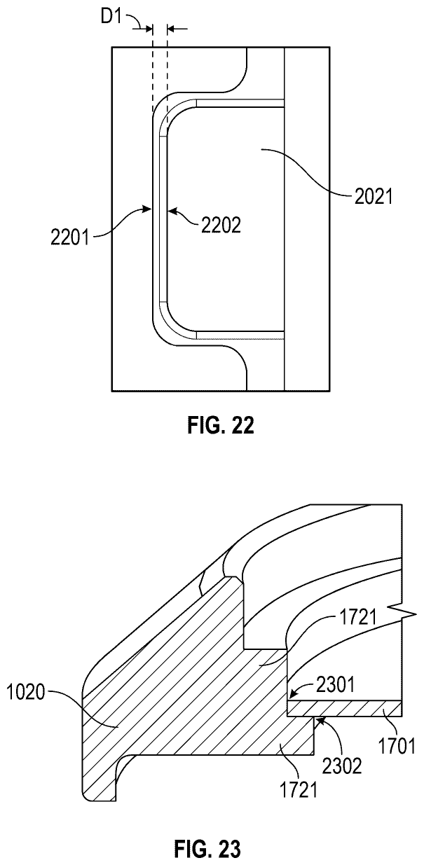

FIG. 22 is a schematic partial enlarged top view of the first plate 1701 and the first liner 1020 shown in FIG. 20, according to one or more embodiments.

FIGS. 20-22 are described together. The first liner 1020 includes a plurality of tab extensions 2021, 2022 extending radially inwardly and into openings formed in an outer edge of the first plate 1701. The tab extensions 2021, 2022 respectively include an inner face 2201 and a recessed face 2202 that is recessed by a distance D1 in a radially outwardly direction relative to the inner face 2201. In one or more embodiments, the distance D1 is less than 2.0 mm, such as less than 1.0 mm. In one or more embodiments, the distance D1 is within a range of 0.3 mm to 1.0 mm. The plate injector 1700 facilitates a simple design that is quick and easy to manufacture and install, and facilitates modularly replacing the plate(s) 1701, 1702 to facilitate a variety of flow opening 1430 patterns, shapes, and sizes. FIG. 23 is a schematic partial perspective cross-sectional view of the first plate 1701 and the first liner 1020 shown in FIGS. 20-22, according to one or more embodiments.

In one or more embodiments, the first plate 1701 is welded to the one or more first ledges 1721 of the first liner 1020. A weld line 2301 (such as a weld bead) is used at an interface between the first liner 1020 and an upper side of an outer edge of the first plate 1701. A weld line 2302 (such as a weld bead) can be used at an interface between the first liner 1020 and a lower side of the outer edge of the first plate 1701. The weld line(s) 2301, 2302 can extend along part of a circumference of the first plate 1701, or along an entirety of the circumference of the first plate 1701. The weld line(s) 2301, 2302 can be part of fillet welds. In one or more embodiments the first plate 1701 is formed of a transparent material (such as a clear quartz) and the first liner 1020 is formed of an opaque material (such as opaque quartz). The welding can reduce or eliminate leakage of gas (such as process gas P1) between the first plate 1701 and the first liner 1020. In one or more embodiments, the first plate 1701 is welded to the first liner 1020, and then the flow openings 1430 are formed in the first plate 1701. The present disclosure also contemplates that the flow openings 1430 can be formed after the welding.

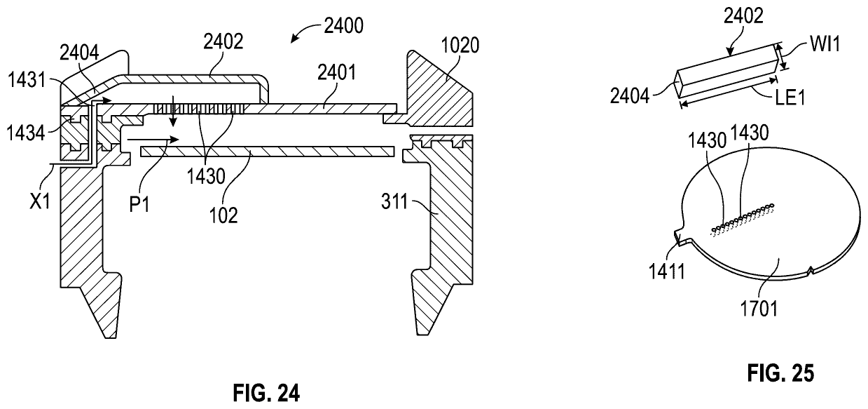

FIG. 24 is a schematic partial side cross-sectional view of a plate injector 2400 disposed in the processing chamber 1000, according to one or more embodiments.

The plate injector 2400 includes a first plate 2401 having the flow openings 1430 and a second plate 2402. The second plate 2402 is a bar frame that can have a U-shaped cross section. The second plate 2402 covers the flow openings 1430 and extends partially across the first plate 2401.

FIG. 25 is a schematic perspective exploded view (from above) of the first plate 2401 and the second plate 2402 shown in FIG. 24, according to one or more embodiments. The second plate 2402 includes a tapered section 2404 aligned above the one or more inlet openings 1431. The second plate 2402 has a length LE1 that is larger than a width WI1. The length LE1 and the width W11 are smaller than a lateral dimension (such as a diameter) of the first plate 1701.

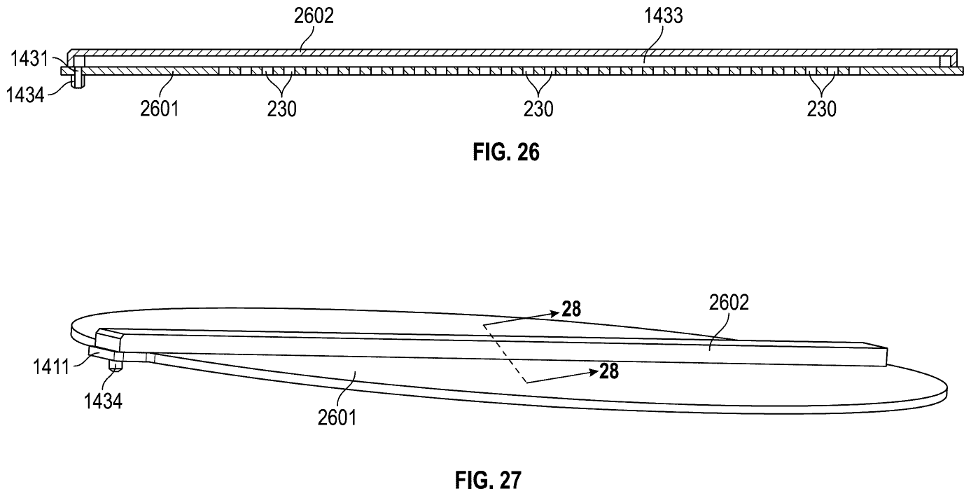

FIG. 26 is a schematic partial side cross-sectional view of a plate injector 2600, according to one or more embodiments.

The plate injector 2600 includes a first plate 2601 and a second plate 2602 covering the openings 230 of the first plate 2601. The second plate 2602 is a bar frame that can have a U-shaped cross section. The second plate 2602 extends across at least 50%, such as at least 80% of a dimension (such as a diameter) of the first plate 2601. The second plate 2602 is coupled (such as welded, for example fillet welded) to the first plate 2601.

FIG. 27 is a schematic perspective view of the plate injector 2600 shown in FIG. 26, according to one or more embodiments.

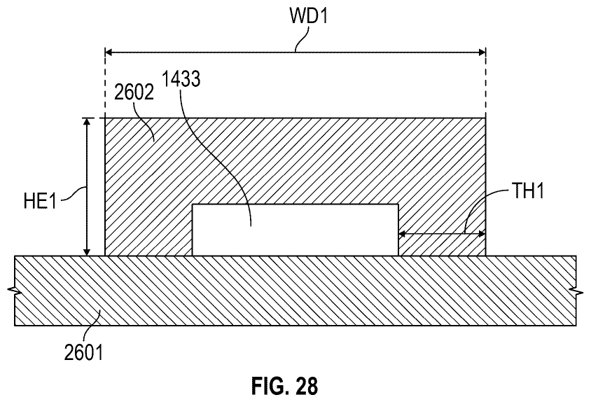

FIG. 28 is a schematic cross-sectional view, along Section 28-28 shown in FIG. 27, of the plate injector 2600 shown in FIG. 26, according to one or more embodiments.

The second plate 2602 has a height HE1, a width WD1 larger than the height HE1, and a thickness TH1 less than the height HE1. In one or more embodiments, the height HE1 is 10 mm or less, the width WD1 is 15 mm or more, and the thickness TH1 is 5 mm or less (such as within a range of 3 mm to 5 mm).

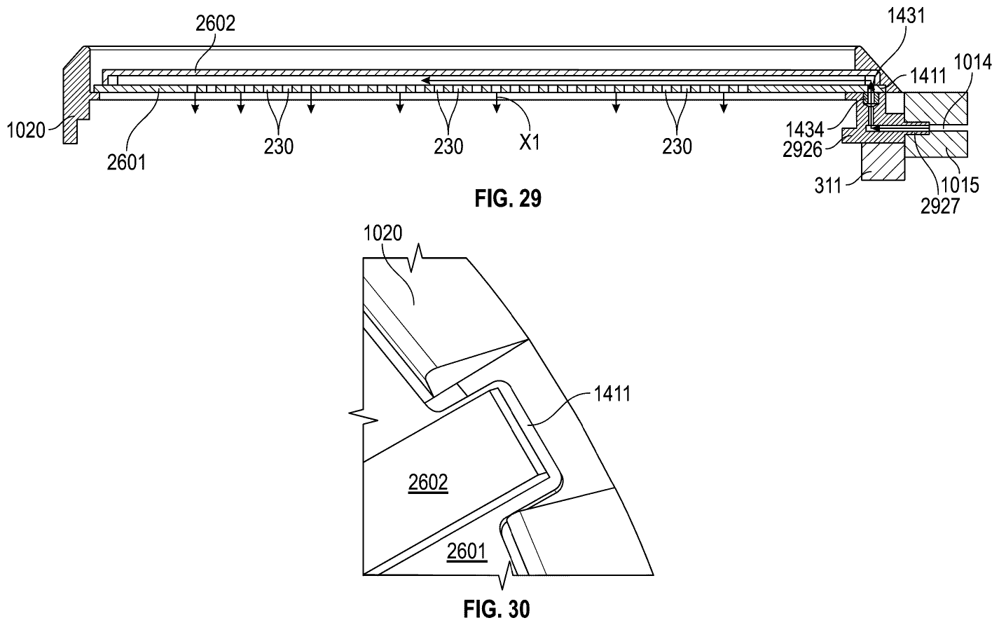

FIG. 29 is a schematic partial side cross-sectional view of the plate injector 2600 shown in FIG. 26 disposed in the processing chamber 1000, according to one or more embodiments.

An inject block 2926 is fluidly connected between the one or more inlet openings 1431 of the first plate 2601 and the one or more gas inlets 1014 of the injector 1015. The present disclosure contemplates that the inject block 2926 can be disposed at the inject side of the chamber (e.g., in place of the inject block 1026 shown in FIG. 1), at the exhaust side of the chamber, and/or at the intersection side of the chamber. At least a section 2927 (such as a sleeve section) of the inject block 2926 extends into the injector 1015. The extension 1434 of the plate injector 2600 extends at least partially into one or more openings (e.g., recess(es)) of the inject block 2926.

FIG. 30 is a schematic partial perspective top view of the plate injector 2600 disposed in the processing chamber 1000 as shown in FIG. 29, according to one or more embodiments.

The tab extension 1411 of the first plate 2601 and the second plate 2602 extend into an opening 3021 (such as a recess) of the first liner 1020. The opening 3021 can define a recessed surface 3022 on which the tab extension 1411 can rest.

Benefits of the present disclosure include activation of one or more process gases, reduced or eliminated depletion of process gases, injection of supplemental gas at any location along a primary flow path, increased concentration of process gases along flow path, adjustability of precursor concentrations, reduced or eliminated obstructions for processing volume space and thermal adjustability, and reduced effects on substrates. Benefits also include increased deposition efficiency, and decreased maintenance and decreased cost. Benefits further include reduced obstructions in the chamber (such as in the processing volume), thermal adjustability, adjustability of activation, such as based on varying gas compositions and/or gas flow rates.

It is contemplated that one or more aspects disclosed herein may be combined. As an example, one or more aspects, features, components, operations and/or properties of the processing chamber 1000, the injector 1015, the one or more exhaust outlets 116, the cross-flow injector 210, the inject block 1026, the openings 230, the one or more valves 214, the first spatial injector 220, the second spatial injector 225, the openings 230, the first spatial inlet 221, the second spatial inlet 226, the first curved inlet 621, the second curved inlet 626, first plurality of inlets 721, the second plurality of inlets 726, the upper openings 830, the cross flow spatial injector 910, plate injector 1010, the intersection injector 1125, the intersection flow conduit 1225, the method 1300, the plate injector 1400, the flow openings 1430, the plate injector 1700, the plate injector 2400, the plate injector 2600, and/or the inject block 2926 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate processing chamber, comprising:
a chamber body at least partially defining an internal volume;
a substrate support disposed in the internal volume;
an injector operable to provide one or more process gases into a processing volume of the internal volume; and
a spatial injector operable to provide one or more first supplemental gases into the processing volume at a location radially inwardly of an outer edge of the substrate support.

2. The substrate processing chamber of claim 1, wherein the spatial injector comprises one or more tube sections.

3. The substrate processing chamber of claim 1, wherein the spatial injector comprises one or more curved sections.

4. The substrate processing chamber of claim 1, wherein the spatial injector comprises one or more mesh sections.

5. The substrate processing chamber of claim 1, further comprising a second spatial injector operable to provide one or more second supplemental gases into the processing volume at a second location radially inward of an outer edge of the substrate support.

6. The substrate processing chamber of claim 5, wherein the second spatial injector is offset from the spatial injector along a radial direction of the substrate support.

7. The substrate processing chamber of claim 5, wherein the spatial injector and the second spatial injector are oriented to intersect each other.

8. The substrate processing chamber of claim 5, wherein the spatial injector and the second spatial injector comprises one or more lower openings and one or more upper openings.

9. A substrate processing chamber, comprising:
a chamber body at least partially defining an internal volume;
a substrate support disposed in the internal volume;
an injector operable to provide one or more process gases into a processing volume of the internal volume; and
a plate injector disposed between the substrate support and a lid of the substrate processing chamber, the plate injector comprising one or more openings operable to provide one or more supplemental gases into the processing volume at one or more locations disposed radially inwardly of an outer edge of the substrate support.

10. The substrate processing chamber of claim 9, wherein the plate injector comprises:
a first face having the one or more openings;
a second face; and
one or more channels disposed between the first face and the second face, the one or more channels in fluid communication with the one or more openings.

11. The substrate processing chamber of claim 9, wherein the one or more openings of the plate injector include a plurality of openings disposed between a center of the plate injector and an outer edge of the plate injector, the plurality of openings are disposed on one side of the center of the plate injector, the plurality of openings have a size that is a ratio of a thickness of the plate injector, and the ratio is 0.3 or less.

12. The substrate processing chamber of claim 10, wherein the plate injector comprises:
a first plate including the one or more openings, the first plate comprising an extension extending relative to the first face; and
a second plate covering the first plate to define the one or more channels between the first plate and the second plate.

13. The substrate processing chamber of claim 10, wherein the plate injector comprises:
a first plate including the one or more openings, the first plate supported by one or more first ledges of the chamber body; and
a second plate spaced from the first plate to define the one or more channels between the first plate and the second plate, the second plate supported by one or more second ledges of the chamber body.

14. The substrate processing chamber of claim 13, wherein:
the chamber body comprises a plurality of first tab extensions extending radially inwardly and into openings formed in an outer edge of the first plate; and
the second plate comprises a plurality of second tab extensions extending radially outwardly and into the chamber body.

15. The substrate processing chamber of claim 10, wherein the plate injector comprises:
a plate including the one or more openings; and
a bar frame covering the one or more openings of the plate to define the one or more channels between the plate and the bar frame, the bar frame having a width that is less than a diameter of the plate, wherein the bar frame and a tab extension of the plate extend into an opening of the chamber body.

16. The substrate processing chamber of claim 9, wherein the plate injector is disposed to separate the processing volume from a remote volume of the internal volume, and the remote volume is disposed between the plate injector and a window.

17. The substrate processing chamber of claim 9, wherein the one or more openings of the plate injector are disposed at a non-zero angle relative to a flow opening of the injector.

18. A method of substrate processing comprising:
heating a substrate positioned on a substrate support within an internal volume;
flowing one or more process gases into a processing volume at a first location;
flowing one or more supplemental gases into the processing volume at one or more second locations radially inwardly of the first location; and
flowing the one or more process gases across the substrate; and
flowing the one or more supplemental gases over the substrate.

19. The method of claim 18, wherein the one or more process gases and the one or more supplemental gases are the same in composition.

20. The method claim 18, wherein the one or more process gases and the one or more supplemental gases are different from one another in composition.
